(19) United States
(12) Patent Application Publication
(10) Pub. No.: US 2022/0077817 A1
(43) Pub. Date: Mar. 10, 2022

(54) BIFACIAL PHOTOVOLTAIC SOLAR PANEL AND SOLAR PANEL ASSEMBLY

(71) Applicant: MORGAN SOLAR INC., Toronto (CA)

(72) Inventors: Stephen CAELERS, Toronto (CA); Brett BARNES, Toronto (CA); Muny TRAM, Toronto (CA)

(21) Appl. No.: 17/299,873

(22) PCT Filed: Dec. 13, 2018
(86) PCT No.: PCT/IB2018/060034

§ 371 Date: Jun. 4, 2021

(51) Int. Cl. H02S 40/22; H02S 20/32

(52) U.S. Cl. CPC H02S 40/22; H02S 20/32

(57) ABSTRACT

A bifacial photovoltaic solar panel and solar panel assembly. The panel includes at least one transparent layer; bifacial photovoltaic cells positioned and arranged to absorb irradiance incident thereon on both sides; and at least one optical element. To form the assembly, the panel is connected to a mounting assembly. When in use, the mounting assembly obscures at least a portion of the panel second side, some cells receiving less irradiance via the panel second side than other cells due to the mounting assembly obscuration, and the optical element is arranged to direct irradiance incident thereon via the panel first side onto the first sides of the subset of cells whereby at least a portion of irradiance having been prevented from reaching the second sides of the cells by the mounting assembly is compensated for by irradiance reflected by the optical element onto the first sides of the cells.

### TECHNICAL FIELD

The present technology relates generally to bifacial photovoltaic solar panels and assemblies.

### BACKGROUND

In the field of solar energy, conventional photovoltaic panels have traditionally been used to generate electricity from sunlight. These panels generally consist of arrays of photovoltaic cells connected in series and in parallel within a solar module, with each cell consisting of a semiconductor substrate (e.g. monocrystalline or polycrystalline silicon, multijunction III-V semiconductor cells, etc.). The photovoltaic cells are electrically connected together with a conductor in order to allow generated electricity to flow from the cells to an electrical output.

The current created by the photovoltaic cells is a function primarily of the conversion efficiency of the cell and the amount of irradiance being absorbed by the cell. For a given manufacturing process, the photovoltaic cells will generally not be identical, as a small amount of variation in the cell efficiency is generally unavoidable. During production of photovoltaic cells, the cells are tested and separated into “bins” (groups) according to their measured efficiency. When the photovoltaic cells are then assembled into solar panels, cells in any given solar panel are chosen “from the same bin” to ensure that all the cells in a given module have roughly the same measured efficiency.

As the photovoltaic cells in a solar panel are generally connected in series (with as few as one string per panel), the cell producing the least current acts as a current limiter. Thus, for example, when exposed to a given amount of irradiance, the least efficient cell in the series sets the current of the whole circuit. As such, shading can have a significant impact on solar panel performance. For example, if one cell in a series connected panel is shaded 100% then the output of the whole panel circuit can be reduced to zero.

One proposed solution to this issue of shading, for example, includes including bypass diodes to create substrings within the solar panel. When one cell or substring starts to limit the current (because of shading or for some other reason), power drops until a threshold is reached and the current begins to flow through the bypass diode, effectively isolating the underperforming substring from the circuit.

Typically, panels include 3 to 6 such substrings. In such an arrangement, 100% shading of a single cell reduces overall power output of the panel by approximately one third to one sixth respectively. This is still a significant loss of overall power output and requires the additional assembly and material cost of including the bypass diodes. Additionally, in the foregoing example, the bypass diodes do not provide any improvement on power output in cases where an underperforming cell is reducing current by less than one third or one sixth (as the case may be).

There has also been work to increase electricity production by solar panels by utilizing bifacial photovoltaic cells that can absorb light via both their front and back surfaces. In addition to absorbing direct light from the sun and diffuse light from the sky, bifacial panels can also absorb reflected light from the ground and light from low near the horizon (depending on their orientation). Solar panels utilizing bifacial cells still suffer from power reduction due to shading, however, and the solar panel mounting structure and hardware can further create shading on some of the photovoltaic cells on the back or front of the panel, depending on the specific mounting structure.

It is therefore a desire for solar panel assemblies that address at least one of the above described inconveniences.

### SUMMARY

It is an object of the present technology to ameliorate at least one of the inconveniences (be it one of those mentioned hereinabove, or otherwise) present in the prior art.

Some embodiments of the current technology provide a bifacial photovoltaic panel suitable for mounting on a mounting structure. The panel includes at least one string of bifacial solar cells and transparent materials that permit light to be absorbed by at least one of the bifacial cells from both sides. The mounting structure to which the panel is attached partially obscures at least one of the bifacial solar cells in the array. Due to a variable spacing between solar cells in a same string in the panel and an optical layer which resides in the spacing between the solar cells that redirects some incident light on either or both the top and bottom of the panel to at least one partially obscured solar cells in the array, the current is boosted from the partially obscured solar cell. This can reduce or eliminate (i.e. reducing to zero) the degree to which the partially obscured solar cell acts as a current limiter for the remaining bifacial cells.

In some embodiments of the current technology, there is provided a bifacial photovoltaic solar panel having a first side and a second side opposite the first side. The panel includes at least one transparent layer; a plurality of bifacial photovoltaic cells supported by the at least one transparent layer, the plurality of cells being distributed across the at least one transparent layer, a first side of each of the photovoltaic cells being positioned and arranged to absorb irradiance incident on the first side of the panel and a second side of each of the photovoltaic cells being positioned and arranged to absorb irradiance incident on the second side of the panel; and at least one optical element supported by the at least one transparent layer and disposed between some of the plurality of cells, when in use, the panel being connected to a mounting assembly, and at least a portion of the mounting assembly obscuring at least a portion of the second side of the panel, the second sides of a subset of cells of the plurality of cells receiving less irradiance via the second side of the panel than the second sides of other cells of the plurality of cells due to obscuration by the mounting assembly, the at least one optical element being structured, positioned, oriented and arranged within the panel to direct at least some irradiance incident thereon via the first side of the panel onto the first sides of the subset of cells whereby at least a portion of irradiance having been prevented from reaching the second sides of the cells of the subset of cells by the mounting assembly is compensated for by irradiance reflected by the at least one optical element onto the first sides of the cells of the subset of cells.

In some embodiments, the at least one optical element is at least one reflective optical element.

In some embodiments, the at least one optical element is three optical elements; each optical element extends across the panel; one of the optical elements extending through a center of the panel; and remaining elements of the two optical elements are parallel to and disposed on opposite sides of the optical element extending through the center of the panel.

In some embodiments, the at least one optical element is two reflective optical elements; each reflective optical element extends across the panel; and the reflective optical elements are disposed on opposite sides of a center of the panel.

In some embodiments, the at least one optical element is disposed adjacent an exterior edge of the panel.

In some embodiments, the mounting assembly includes a frame that supports exterior edges of the panel; the at least one optical element is four reflective optical elements; each reflective optical element is disposed adjacent to one of the exterior edges of the panel; and at least some of the subset of cells are disposed adjacent the reflective optical elements.

In some embodiments, the at least one transparent layer is a first transparent layer; the panel further comprises a second transparent layer; and the plurality of photovoltaic cells are disposed between the first transparent layer and the second transparent layer.

In some embodiments, the plurality of bifacial photovoltaic cells are electrically connected in series.

In some embodiments, at least one of the subset of cells and at least one of the other cells are electrically connected in series.

In some embodiments, the at least one reflective optical element comprises a series of reflective facets extending across a width of the panel generally parallel to the subset of cells.

In some embodiments, a spacing between rows of the subset of cells and rows of the other cells of the plurality of cells is greater than a spacing between rows of the other cells of the plurality of cells.

In another aspect, there is provided a solar panel assembly including at least one bifacial solar panel according to any of the above embodiments and the mounting assembly connected to the at least one panel.

In some embodiments, the mounting assembly includes at least one torsion tube; the at least one panel is connected to the at least one torsion tube; and the at least one optical element extends across the at least one panel parallel to the at least one torsion tube.

In some embodiments, the mounting assembly includes a torsion tube; the at least one panel is a first panel and a second panel; the at least one optical element of the first panel is disposed adjacent a first exterior edge of the first panel; the at least one optical element of the second panel is disposed adjacent a first exterior edge of the second panel; the first panel is connected to the torsion tube proximate the corresponding first exterior edge; the second panel is connected to the torsion tube proximate the corresponding first exterior edge; and the at least one optical element of the first panel, the at least one optical element of the second panel, and the torsion tube are arranged parallel to one another.

In some embodiments, the mounting assembly includes two support trusses; the at least one panel is connected to the support trusses; and the at least one optical element extends across the at least one panel parallel to the support trusses.

In some embodiments, the mounting assembly includes a rectangular frame; the at least one panel is supported by the rectangular frame via exterior edges of the at least one panel; the at least one optical element is four reflective optical elements; and each reflective optical element is disposed adjacent one of the exterior edges of the panel; and at least some of the subset of cells are disposed adjacent the reflective optical elements.

According to yet another aspect, there is provided a bifacial photovoltaic solar panel including at least one transparent layer; a first plurality of bifacial photovoltaic cells supported by the at least one transparent layer, each photovoltaic cell of the first plurality of cells having a first surface area; a second plurality of bifacial photovoltaic cells supported by the at least one transparent layer, each photovoltaic cell of the second plurality of cells having a second surface area, the second surface area being greater than the first surface area, each bifacial photovoltaic cell of the first plurality and of the second plurality having a first side and a second side.

In some embodiments, when the panel is in use, the panel is connected to a mounting assembly, the first side of each cell is arranged and oriented to receive direct solar irradiance via a first side of the panel, at least a portion of the mounting assembly obscures at least a portion of a second side of the panel, the second side of the panel being opposite the first side of the panel, at least a subset of the second plurality of cells receives less irradiance than other cells via the second side of the panel due to obscuration by the mounting assembly, and at least a portion of irradiance obscured by the mounting assembly on the second side of the subset of the second plurality of cells is compensated by greater irradiance collection by the larger surface area of the subset of the second plurality of cells compared to the first plurality of cells.

In some embodiments, at least some of the first plurality of cells are electrically connected in series to at least some of the second plurality of cells.

In some embodiments, each one of the second plurality of bifacial photovoltaic cells is formed from at least two smaller bifacial photovoltaic cells electrically connected in parallel.

In yet another aspect, there is provided a bifacial photovoltaic solar panel having a first side and a second side opposite the first side. The panel includes at least one transparent layer; a plurality of bifacial photovoltaic cells supported by the at least one transparent layer, the plurality of cells being distributed across the at least one transparent layer, a first side of each of the photovoltaic cells being positioned and arranged to absorb irradiance incident on the first side of the panel and a second side of each of the photovoltaic cells being positioned and arranged to absorb irradiance incident on the second side of the panel; and at least one optical element supported by the at least one transparent layer and disposed between some of the plurality of cells, the at least one optical element being structured, positioned, oriented and arranged within the panel to direct at least some irradiance incident thereon via the first side of the panel onto the first sides of a subset of cells disposed around the at least one optical element, a spacing between rows of the subset of cells and rows of other cells of the plurality of cells being greater than a spacing between rows of the other cells of the plurality of cells.

In yet another aspect, there is provided a bifacial photovoltaic solar panel including at least one transparent layer; a first plurality of bifacial photovoltaic cells supported by the at least one transparent layer, each photovoltaic cell of the first plurality of cells having a first efficiency; a second plurality of bifacial photovoltaic cells supported by the at least one transparent layer, each photovoltaic cell of the second plurality of cells having a second efficiency, each bifacial photovoltaic cell of the first plurality and of the second plurality having a first side and a second side, the second efficiency being greater than the first efficiency; and when in use, the panel being connected to a mounting assembly, the first side of each cell being arranged and oriented to receive direct solar irradiance via a first side of the panel, at least a portion of the mounting assembly obscuring at least a portion of a second side of the panel, the second side of the panel being opposite the first side of the panel, at least a subset of the second plurality of cells receiving less irradiance than other cells via the second side of the panel due to obscuration by the mounting assembly, and at least a portion of irradiance obscured by the mounting assembly on the second side of the subset of the second plurality of cells being compensated by greater efficiency to collect irradiance of the subset of the second plurality of cells compared to the first plurality of cells.

In some embodiments, at least some of the first plurality of cells are electrically connected in series to at least some of the second plurality of cells.

For purposes of this application, terms related to spatial orientation such as top and bottom, should be understood in a frame of reference of a solar panel, where the top surface is the surface oriented towards the sky. Terms related to spatial orientation when describing or referring to components or sub-assemblies of the solar panel separately therefrom should be understood as they would be understood when these components or sub-assemblies are mounted in the solar panel, unless specified otherwise in this application.

Embodiments of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of embodiments of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 is a side view of a schematically illustrated solar panel assembly according to one embodiment of the present technology;

FIG. 2 is a close-up view of portions of the solar panel assembly of FIG. 1;

FIG. 3 is a perspective view from a top, front side of a solar panel and a torsion tube of the solar panel assembly of FIG. 1;

FIG. 4 is a top plan view of the solar panel of FIG. 3;

FIG. 5 is a partial cross-sectional view of the solar panel of FIG. 3, taken along line 5-5 of FIG. 4;

FIG. 6 is a perspective view from a top, front side of a solar panel assembly according to another embodiment of the present technology with the mounting assembly shown in dotted lines;

FIG. 7 is a perspective view of a solar panel assembly according to another embodiment of the present technology;

FIG. 8 is a top plan view of a solar panel of the solar panel assembly of FIG. 7;

FIG. 9 is a top plan view of a solar panel assembly, including a solar panel and a corresponding frame, according to another embodiment of the present technology;

FIG. 10 is a partial cross-sectional view of the solar panel assembly of FIG. 9, taken along line 10-10 of FIG. 9;

FIG. 11 is a top plan view of a solar panel according to yet another embodiment of the present technology;

FIG. 12A is a cross-sectional view of the solar panel assembly of FIG. 11, taken along line 12-12 of FIG. 11;

FIG. 12B is a cross-sectional view of yet another embodiment of a solar panel assembly including the solar panel of FIG. 11;

FIG. 13 is a top plan view of a solar panel according to yet another embodiment of the present technology;

FIG. 14 is a cross-sectional view of the solar panel assembly of FIG. 13, taken along line 14-14 of FIG. 13; and

FIG. 15 is a top plan view of a solar panel according to yet another embodiment of the present technology.

It should be noted that the Figures are not necessarily drawn to scale.

### DETAILED DESCRIPTION

The present technology will now be described in more detail in conjunction with the Figures.

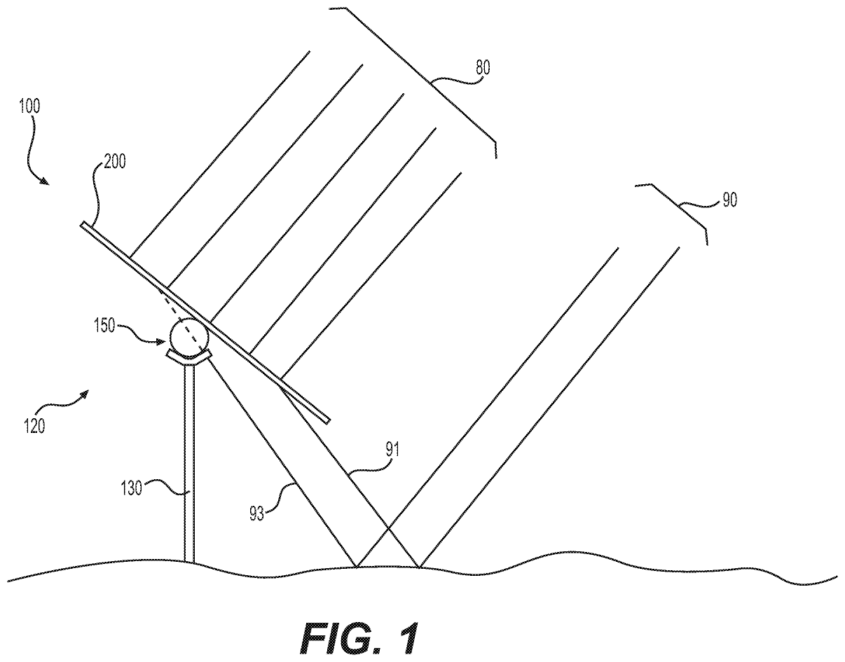

With reference to FIG. 1, a bifacial solar panel assembly 100 according to an embodiment of the present technology is illustrated. The solar panel assembly 100 is generally part of an array of same or similar assemblies, but for simplicity only one assembly 100 is described and illustrated herein.

The solar panel assembly 100 includes a bifacial solar panel 200 mounted on a single-axis tracking mounting assembly 120, shown schematically. It is contemplated that the assembly 100 could include more than one solar panel 200, depending on the embodiment. The bifacial solar panel 200 will described in more detail below.

The mounting assembly 120 includes a support post 130 for supporting remaining portions of the assembly 100, shown schematically. Other embodiments the structure of the post 130 may vary. In one non-limiting example, the support post 130 could be held by stabilizing feet. In other embodiments the support post 130 could be replaced by different support structures. In some embodiments, the mounting assembly 100 is a NX Horizon commercialized by NEXTRACKER, Inc. of Fremont, Calif. and described by U.S. Pat. No. 9,905,717, incorporated herein by reference.

The mounting assembly 120 also includes a torsion tube 150 rotatably connected to the support post 130. The solar panel 200 is fastened to the torsion tube 150, such that rotation of the torsion tube 150 with respect to the support post 130 orients the solar panel 200. Rotation of the torsion tube 150 orients the panel 200 to a preferred angle throughout the day in order to maximize the power generated thereby.

Although not explicitly illustrated, the mounting assembly 120 further includes motors, electronics, etc. to control movement of the torsion tube 150 and the solar panel 200, as well as electrical connections for collecting electricity produced by the solar panel 200.

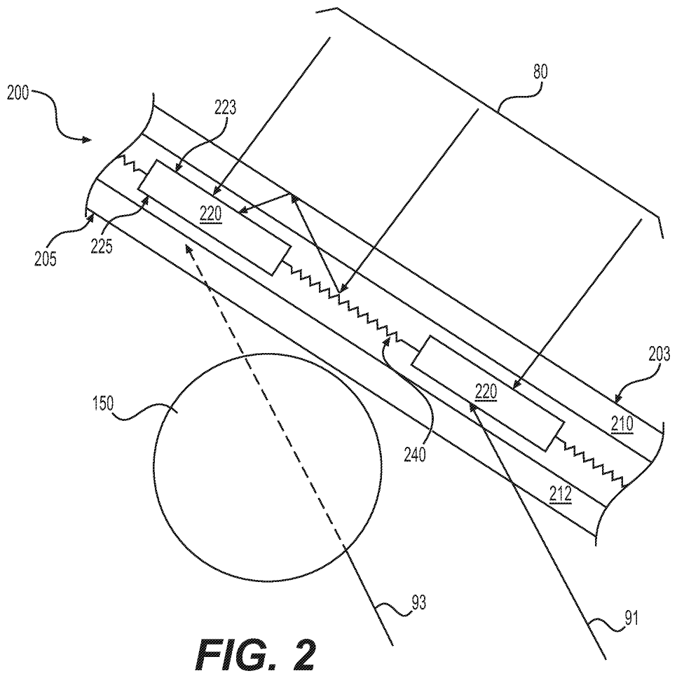

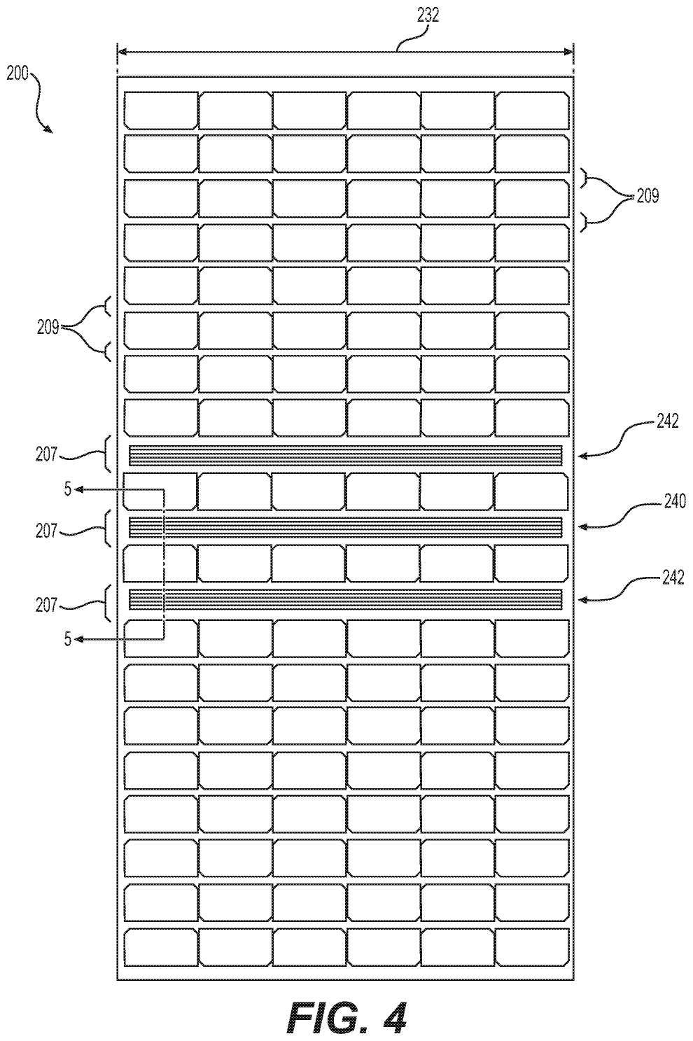

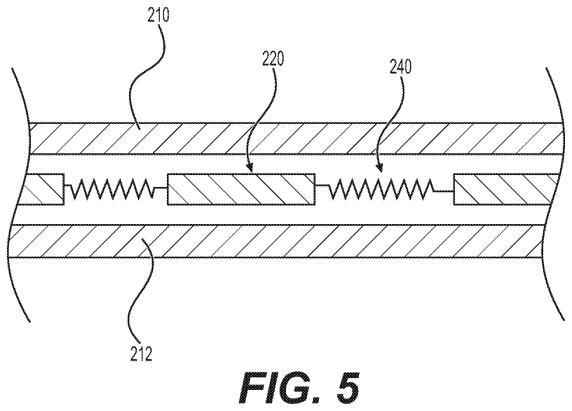

With further reference to FIGS. 2 to 5, the bifacial solar panel 200 will now be described in more detail.

The bifacial solar panel 200 includes a top transparent layer 210 and a bottom transparent layer 212. In the present embodiment, the transparent layers 210, 212 are parallel flat glass plates 210, 212. It is contemplated that the transparent layers 210, 212 could be formed from polyester or another transparent polymer, depending on the embodiment. In various embodiments the transparent layers are from one or more of any number of rigid transparent materials.

The bifacial solar panel 200 also includes a plurality of bifacial photovoltaic cells 220 sandwiched between and supported by the transparent layers 210, 212. In some embodiments, the plurality of bifacial photovoltaic cells 220 are polycrystalline Passivated Emitter and Rear Cell (PERC) cells manufactured by Canadian Solar Inc. of Guelph, Ontario, Canada. The cells 220 are laminated between the transparent layers 210, 212 with an elastomeric. It is contemplated that in some embodiments, the cells 220 and the layers 210, 212 could be additionally or alternatively laminated with a polymeric material such as Ethylene-vinyl acetate or Polyolefin. It is also contemplated that in some embodiments, silicone or epoxy could be used. In other embodiments, other materials could be used. It is also contemplated the panel 200 could be formed from one glass plate onto which the photovoltaic cells 220 could be laminated. Bifacial photovoltaic cells absorb irradiance from two opposite sides of the cell. In the present embodiment, the top side 223 of each photovoltaic cell 220 is positioned and arranged to absorb irradiance incident on the top side 203 of the panel 200 and a bottom side 225 of each photovoltaic cell 220 is positioned and arranged to absorb irradiance incident on the bottom side 205 of the panel 200. The photovoltaic cells 220 are all connected in series, with three bypass diodes (not illustrated). It is contemplated that portions of the photovoltaic cells 220 could connected in series in a group of parallel connected substrings. It is also contemplated that the panel 200 could include more or fewer bypass diodes, depending on the embodiment.

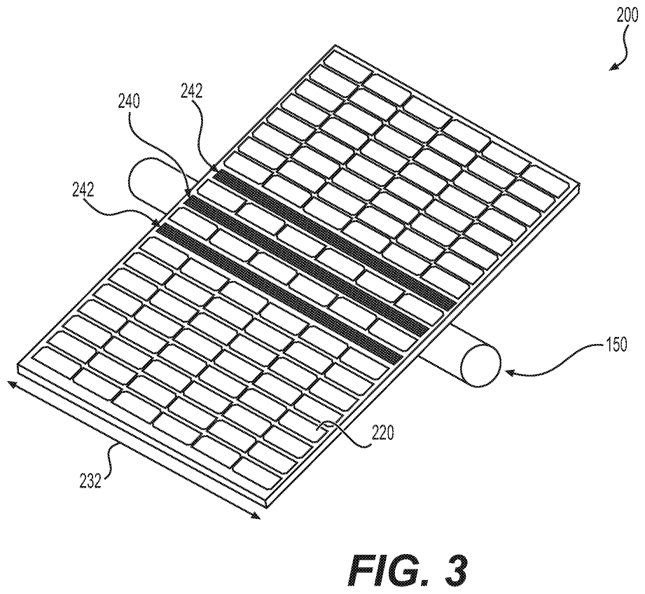

While the photovoltaic cells 220 are generally distributed in an array, it can be seen from at least FIG. 3 that spacing between different rows of cells 220 varies across the panel 200. Specifically, a space 207 between the cells 220 around the center region of the panel 200 is greater than a space 209 between rows of the other cells 220. Depending on the embodiment, it is contemplated that the spacing between various rows of cells 240 or across rows of cells 220 could be different. For example, in another embodiment, the space 207 would be larger or smaller than the spacing illustrated. In another example embodiment, the space 209 could also be larger or smaller.

The bifacial solar panel 200 also includes three optical elements 240, 242 disposed between the photovoltaic cells 220 disposed around the center of the panel 200. A center optical element 240 is disposed at a center of the panel 200 and the remaining two optical elements 242 are disposed on opposite sides of the center optical element 240. In the present embodiment, the optical elements 242 are disposed equidistant from the center of the panel 200 and from the center optical element 240, but this may not be the case in other embodiments.

Each optical element 240, 242 extends across a width 232 of the panel 200 and is disposed between photovoltaic cells 220 disposed in the center of the panel 200. The optical elements 240 are structured, positioned, oriented and arranged within the panel 200 to direct at least some irradiance incident thereon onto the top sides of a subset of the cells 220 as will be described in more detail below. The optical elements 240, 242 in the illustrated embodiment are three reflective optical elements 240, 242. The center optical element 240 extends through the center of the panel 200, generally aligned with and parallel to the torsion bar 150. The other two elements 242 are parallel to and disposed on opposite sides of the center element 240. It is contemplated that the panel 200 could include more or fewer optical elements 240, 242. In other embodiments, optical elements (similar to those shown in FIG. 3 in this embodiment) are in different places on the panel.

In the illustrated embodiment, the optical elements 240, 242 are reflecting optical elements 240. Specifically, each reflecting optical element 240, 242 is formed from a series of reflective facets, or flat faces angles to reflect light incident thereon. The facets extend across the width 232 of the panel 200, generally parallel to the rows of cells 220, including those susceptible to shading. Each optical element 240, 242 includes facets for reflecting in both length-wise directions (perpendicular to the width 232). As such, each optical element 240, 242 has an overall generally zig-zig shape, although this can vary with different embodiments. Each optical element 240, 242 is formed from a thin sheet of Aluminum, pressed formed into the reflective facet form. In some other embodiments, the optical elements 240, 242 can be formed by hot embossing a polymer film such as polycarbonate or poly(methyl methacrylate) (PMMA) and subsequently mirror coating the polymer with a metallic mirror like aluminum or silver. In some other embodiments, the optical element 240, 242 is formed by UV casting of a polymeric resin such as PMMA on a substrate of another polymeric film such as polyethylene terephthalate (PET) and then mirror coating the UV cast optical microstructures.

In some embodiments, one or more of the reflective optical elements 240 could be of a different form, for example in the form of a smooth mirrored surface. It is also contemplated that the optical elements 240 could be other optical elements for redirecting light incident thereon onto the surrounding photovoltaic cells 220. For example, the optical elements 240 could include diffractive elements. The optical elements 240 are supported by the transparent layer 212, with their reflective surfaces oriented toward a top side of the panel 200.

As is mentioned above, the optical elements 240 are arranged to direct at least some light incident thereon onto some of the photovoltaic cells 220. The relative arrangement of the solar panel 200 and the mounting assembly 120 in use will now be described in more detail with reference to FIGS. 1 and 2.

Bifacial photovoltaic cells 220 absorb irradiance from both their top and bottom surfaces to produce current, as is noted above. The solar panel 200 is generally oriented (by the single-axis tracker mounting assembly 120) such that the top surface 203 of the panel 200 and the top surface 223 of the cells 220 receive directly incident light from the sun (rays 80). Light is also incident in areas surrounding the solar panel 200 and is instead incident on other surfaces, including the ground (rays 90). The bottom side 225 of the bifacial photovoltaic cells 220 then generally receive light scattered or reflected from the ground (rays 91), through the bottom transparent layer 212. In some cases, the light could further reflect off the mounting assembly 100, neighboring assemblies 100, etc. and be incident on the bottom side of the panel 200. It is also contemplated that the bottom side of the bifacial cells 220 could receive light from low horizon scattering, depending on the relative position of the sun and the panel 200.

The bottom side of a subset of the photovoltaic cells 220, however, are shadowed by the mounting assembly 120, especially the torsion bar 150. As is illustrated in greater detail in FIG. 2, some light (e.g. ray 93) reflects off the ground toward the bottom side of the panel 200, but is obscured by the torsion bar 150 which extends across the panel 200. While the specific shading pattern changes depending on the orientation of the panel 200, the position of the sun in the sky, etc., shading is generally most likely for the photovoltaic cells 220 near the torsion bar 150.

By way of an example, photovoltaic cells 221 and 222 are generally identical cells, connected in series, the cells 221, 222 being selected from the same bin and therefore having approximately the same efficiency. Both cells 221, 222 absorb (a generally equal amount of) irradiance from their top surfaces (from rays 80). The cell 221 absorbs irradiance from its bottom surface (ray 91) which has reflected or scattered off the ground. The cell 222, however, is shadowed by the torsion bar 150 (indicated by the dashed ray 93) such that the cell 222 absorbs less or no light via its bottom surface. Based only on the light rays 80, 91, 93, the cell 222 would produce less current then the cell 221. As the photovoltaic cells 221, 222 are connected in series, cell 222 would then act as a current limiter on the current produced by cell 221; the benefit of the light absorbed via the back side of the cell 221 would then be reduced.

By the present technology however, inclusion of the optical elements 240 aids in compensating for the irradiance blocked by the torsion bar 150, such that current production by the cell 222 is increased. The optical elements 240 are structured, positioned, oriented and arranged within the panel 200 to direct at least some irradiance incident thereon, via the first side of the panel 200, onto the top sides of some of the cells 220. As such, at least a portion of irradiance that was prevented from reaching the bottom side of the cells by the mounting assembly 120 is compensated for by the irradiance reflected by the optical elements 240 onto the top sides of those cells 220. As the photovoltaic cells 220 near the torsion bar 150 are generally the most likely to be shaded, the optical elements 240 are arranged to direct light onto those photovoltaic cells 220.

Specifically, some light incident on the top side of the panel 200 (ray 83) is incident on the optical element 240 adjacent the cell 222, rather than being absorbed by one of the photovoltaic cells 220. The optical element 240 then reflects the light toward the top transparent layer 210, where almost all of the light experiences total internal reflection (TIR), which in turn directs the light onto the top surface of the cell 222. The cell 222 then produces current from both the irradiance incident directly on the cell 222 from the sun (rays 80) as well as the irradiance redirected from the optical element 240. While the illustrated embodiment utilizes reflecting and TIR in directing the irradiance onto the cell 222, it is contemplated that different arrangements could be implemented. As one non-limiting example, the panel 200 could include waveguides for propagating the light from the optical element 240 to one or more of the cells 220.

It should be noted that light will generally be incident on all of the optical elements 240, which in turn will reflect light onto the cells 220 surrounding the optical elements 240. Depending on the specific embodiment and the orientation of the panel 200, this could include cells 220 which are not being shadowed on either side. Current that could be produced by these cells 220 would generally be greater than the remaining cells 220, and the current output from these cells 220 would be generally limited by the remaining cells 220 of the panel 200 which are not receiving light from both sides as well as from the optical elements 240.

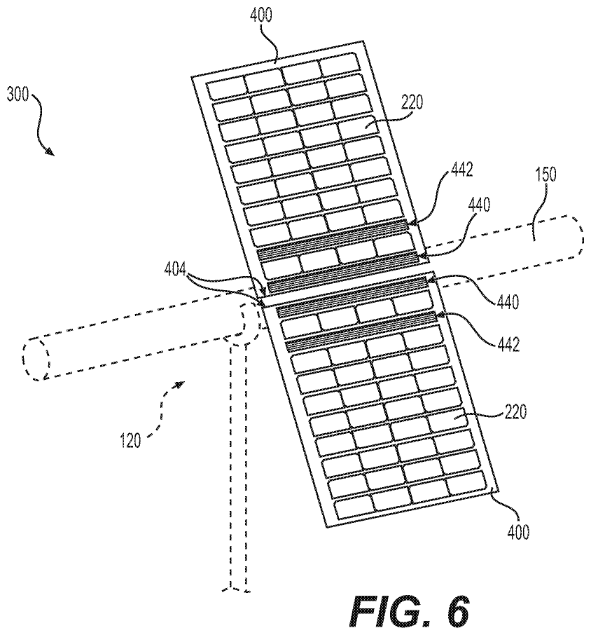

With reference to FIG. 6, another non-limiting embodiment of the present technology is illustrated in the form of a solar panel assembly 300 and two bifacial solar panels 400. Elements of the solar panels 400 that are similar to those of the solar panel 200 retain the same reference numeral and will generally not be described again.

The solar panel assembly 300 includes the mounting assembly 120 with the torsion tube 150, as described above. In this embodiment, two panels 400 are connected to the torsion tube 150. Each panel 400 is connected to the torsion tube 150 proximate one of their exterior edges 404, such that a majority of each panel 400 extends away from the torsion tube 150.

The solar panels 400 are similarly constructed to the panels 200, but due to the mounting arrangement with respect to the torsion bar 150, the area (and thus the cells 220) susceptible to shading is differently located. In order to compensate for possible shading, each panel 400 includes two optical elements 440, 442; the details of the optical elements 440, 442 are generally the same as the elements 240, other than their arrangement. One optical element 440 is disposed adjacent the exterior edge 404 connected to the torsion bar 150. The other optical element 442 of each panel 400 is disposed between two rows of cells 220, but still generally near the exterior edge 404 of the panel 400 connected to the torsion bar 150.

In the present embodiment of the solar panel assembly 300, the optical elements 440 of both panels 400 and the torsion tube 150 are arranged parallel to one another. It is contemplated that the panels 400 could include more optical elements 440. It is also contemplated that the panels 400 could include only one optical element 440, depending on the specific embodiment. While assembly 300 includes two identical panels 400, it is further contemplated that the assembly 300 could include two different embodiments of the solar panel 400. While the two panels 400 are connected to the torsion bar 150 in a mirror-image arrangement in order to balance forces on the bar 150, it is contemplated that one such solar panel 400, connected to the bar 150 in the offset arrangement, could be used depending on the specific embodiment.

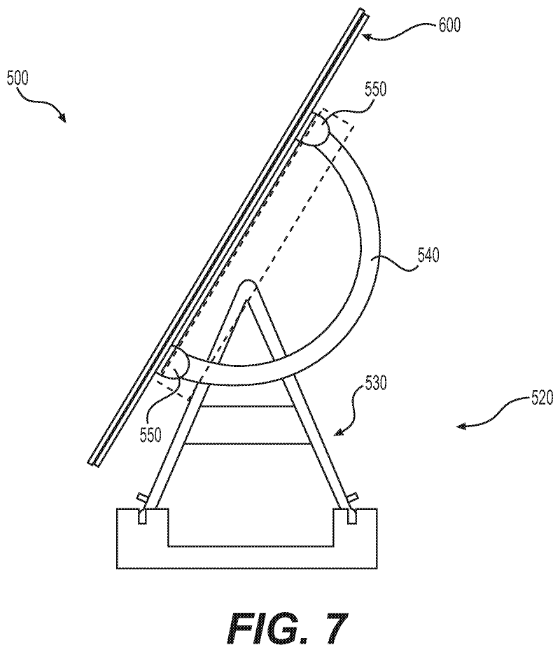

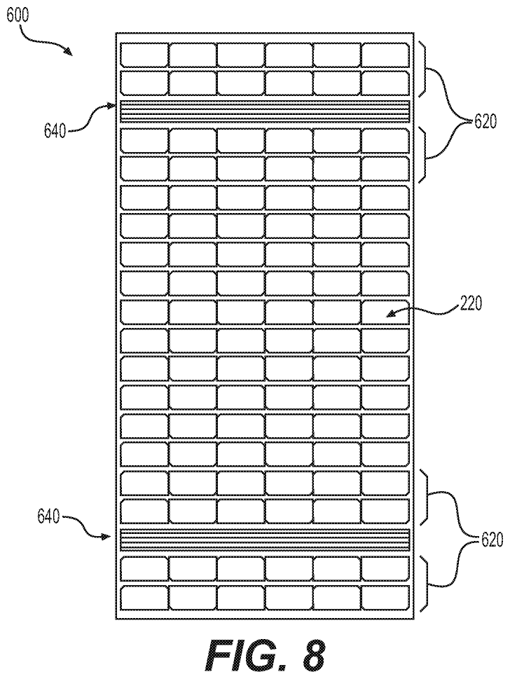

With reference to FIGS. 7 and 8, yet another non-limiting embodiment of a solar panel assembly 500 with a corresponding embodiment of a bifacial solar panel 600 is illustrated. Elements of the solar panel 600 that are similar to those of the solar panel 200 retain the same reference numeral and will generally not be described again.

The solar panel assembly 500 includes a double truss style single-axis tracker mounting assembly 520 supporting the bifacial solar panel 600. The mounting assembly 520 includes a supporting structure 530 for supporting remaining portions of the assembly 500 and a semicircular bar 540 which rotates with respect to the structure 530. Different structures than illustrated are contemplated depending on the specific embodiment.

The semicircular bar 540 connects to two support trusses 550 that extend along a back side of the panel 600. The supporting structure 530 and bar 540 are generally offset to the sides of the panel 600 in order to minimize potential light blocking, although different arrangements are contemplated. Similar to the torsion bar 150 however, the support trusses 550 block a portion of the bottom side of the panel 600 from receiving light and further potentially cast a shadow over adjacent portions of the bottom side of the panel 600.

For this particular embodiment, the panel 600 includes the bifacial photovoltaic cells 220 and two reflective optical elements 640 extending across the width of the panel 600. The details of the optical elements 640 are generally the same as the elements 240, other than their arrangement in the panel 600. The reflective optical elements 640 are disposed on opposite sides of a center of the panel 600 and are generally aligned with and parallel to the support trusses 550. As such, the optical elements 640 are arranged to reflect light onto the cells 220 that are most susceptible to being shadowed by the support trusses 550, indicated as cells 620 as illustrated.

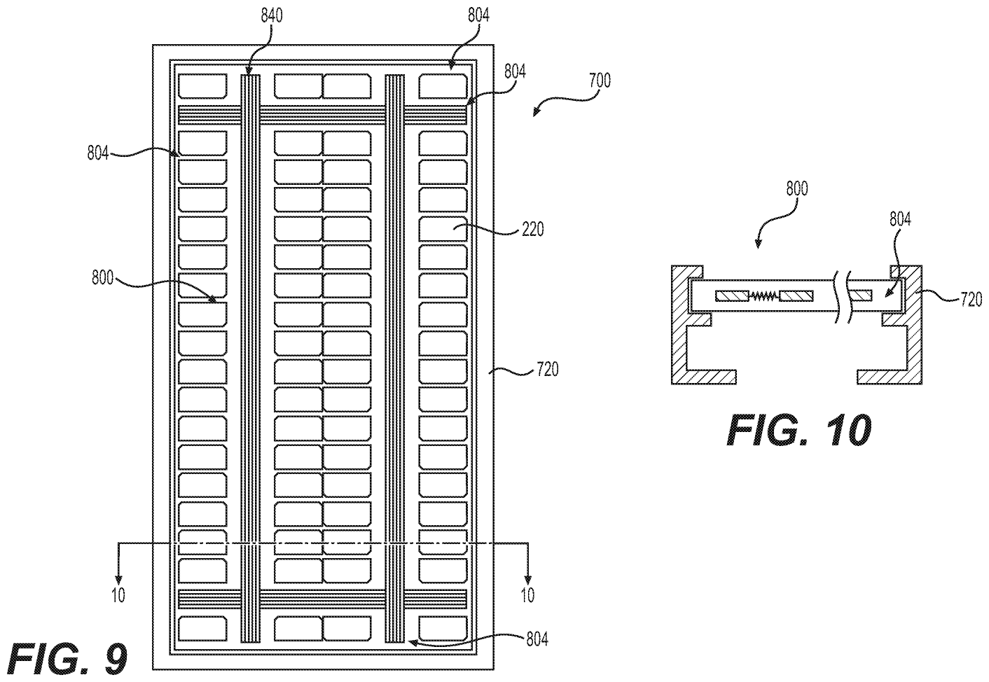

Yet another non-limiting embodiment of a solar panel assembly 700 with a corresponding embodiment of a bifacial solar panel 800 is illustrated in FIGS. 9 and 10. Elements of the solar panel 800 that are similar to those of the solar panel 200 retain the same reference numeral and will generally not be described again.

In place of or in addition to a tracking system, some solar panels are mounted in frames which can be fastened or connected to different installation. In the solar panel assembly 700, the bifacial solar panel 800 is held by a mounting assembly including a rectangular frame 720. The panel 800 is supported by the rectangular frame 720 via exterior edges of the panel 800. Portions of the frame 720 surround the edges of the panel 800 to secure the panel 800.

The panel 800 includes the bifacial photovoltaic cells 220 and four reflective optical elements 840 extending across the panel 800 in different directions. The details of the optical elements 840 are generally the same as the elements 240, other than their arrangement in the panel 800. The details of the optical elements 840 are generally the same as the elements 240, other than their arrangement in the panel 800. It is contemplated that the optical elements 840 could be structured to reflect generally along the same directions, independent of the layout of those optical elements 840. For example, in some embodiments, the reflective facets of each of the optical elements 840 could be oriented to reflect light in the same direction, while the optical elements 840 themselves extend in different directions across the panel 800.

Each reflective optical element 840 is disposed generally near one of the exterior edges 804 of the panel 800, between some of the cells 220. Specifically, the optical elements 840 are separated from the exterior edges 804 by one cell 220. As such, light can be redirected onto the surrounding cells 220 that are susceptible to being shadowed by the frame 720, which surrounds and supports the exterior edges 804. Two of the optical elements 840 are interrupted as they extend across the panel 800. It is contemplated that the four optical elements 840 could be more or fewer elements 840, depending on the particular embodiment.

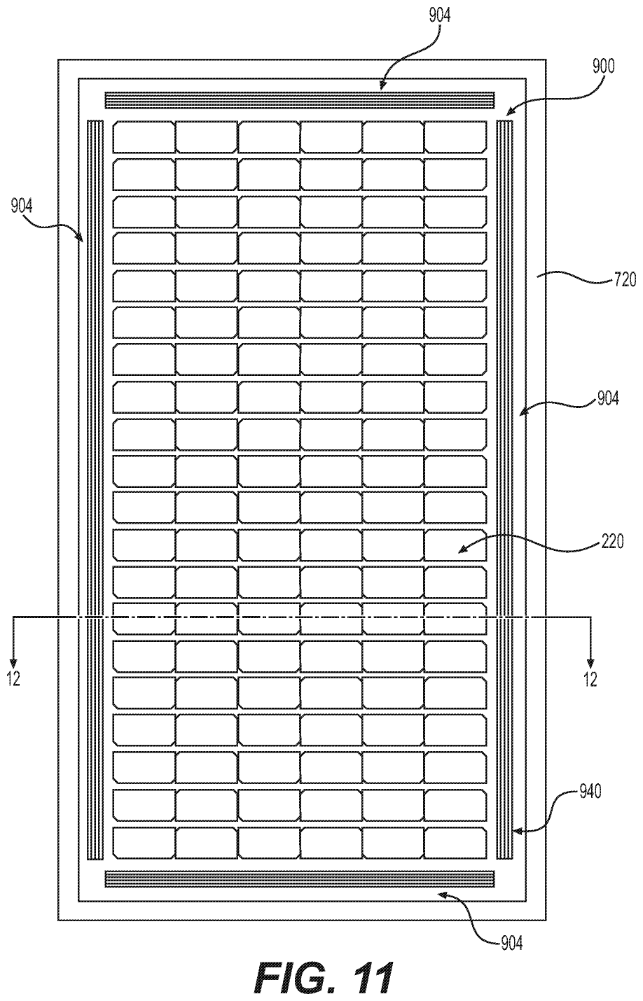

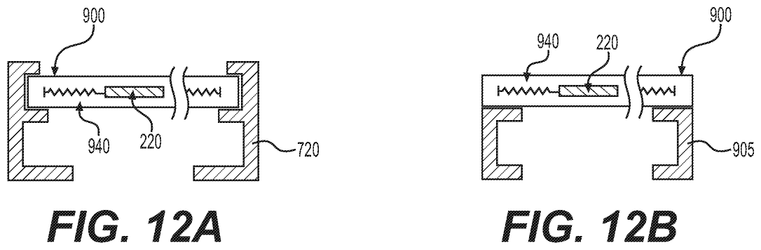

With reference to FIGS. 11, 12A, and 12B, another non-limiting embodiment of a bifacial solar panel 900 will be described. Elements of the solar panel 900 that are similar to those of the solar panel 200 retain the same reference numeral and will generally not be described again.

The solar panel 900 is shown in FIGS. 11 and 12A mounted in the frame 720, described above. The solar panel 900 includes four optical elements 940; the details of the optical elements 940 are generally the same as the elements 240, other than their arrangement in the panel 900. The optical elements 940 are disposed adjacent to the exterior edges of the panel 900 and generally surround the cells 220, such that there are no cells 220 between the optical elements 940 and the exterior edges 904. It is contemplated that the panel 900 could include more or fewer optical elements 940, depending on the embodiment. In some embodiments, the panel 900 could include one optical element, disposed around the cells 220. For example, the optical elements 940 could be integrally connected into one optical element.

As can be seen, the optical elements 940 generally form a border around the cells 220, with some of the cells 220 being disposed adjacent to the optical elements 940. At least some of the light blocked by the frame 720 and prevented from being incident on the back side of the cells 220 near the edge is thus compensated for by the additional light redirected onto the top sides of those same cells 220.

FIG. 12B illustrates in cross-section another possible embodiment of a frame 905 that could be used to support the panel 900. While the frame 905 blocks less of the top side of the panel 900, portions of the frame 905 could still obscure the bottom side of the panel 900.

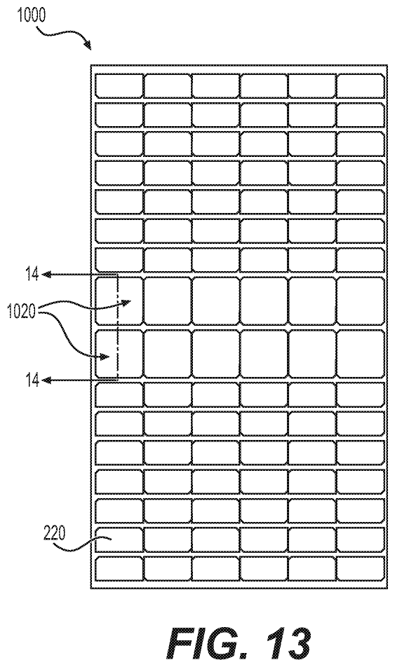

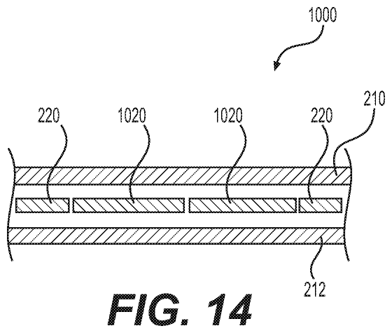

With reference to FIGS. 13 and 14, another non-limiting embodiment of a bifacial solar panel 1000 to be mounted in the single-axis tracker 120 will now be described. Elements of the solar panel 1000 that are similar to those of the solar panel 200 retain the same reference numeral and will generally not be described again.

The bifacial photovoltaic solar panel 1000 includes two different groups of bifacial photovoltaic cells: the photovoltaic cells 220 and photovoltaic cells 1020 disposed generally in the center of the panel 1000. As with earlier embodiments, one or more of the cells 220 are electrically connected in series to one or more of the cells 1020.

The two rows of cells 1020 are arranged generally aligned with and parallel to where the torsion bar 150 is disposed when the panel 1000 is connected to the mounting assembly 120. The two rows of cells 1020 are so located to be generally in the area most susceptible to shading by the torsion bar 150 fastened to a center of the panel 1000. It is contemplated that the panel 1000 could include more or fewer of the cells 1020. It is also contemplated that the cells 1020 could be arranged differently, for example with the cells 1020 being disposed in different regions of the panel 1000 in embodiments using different mounting assemblies. In one non-limiting example, the panel 1000 could be mounted to the torsion bar 150 via one of its exterior edges (similar to the panels 400 for example) and the cells 1020 could then be disposed adjacent the exterior edge of the panel 1000.

The cells 1020 have a greater active surface area (both on the top and bottom sides) than the cells 220, illustrated by appearing larger in the Figure, which allows the cells 1020 to absorb a greater portion of the irradiance incident on either side of the panel 1000. As such, in this embodiment, at least a portion of the irradiance obscured by the mounting assembly 120 on the bottom side of the cells 1020 is compensated by the greater irradiance collection by the larger surface area of the cells 1020 compared to the cells 220. The current across a given string of cells 220, 1020 is thus maintained in this embodiment by the cells 1020 creating a higher current from the irradiance absorbed via their top surfaces (due to the larger surface area), which should more closely match the current produced by the cells 220 from irradiance absorbed from the top and bottom sides.

As is generally illustrated, the photovoltaic cells 220 are “half-cells”, or standardized photovoltaic cells having been cut in half. In the present embodiment, the cells 1020 are simply full-sized cells 1020. Depending on the embodiment, the cells 220, 1020 could have different sizes. For example, the cells 220 could be full-sized standard cells, and the cells 1020 could be larger, non-standard photovoltaic cells. In the present embodiment, the surface area ratio of the cells 1020 to the cells 220 is 2:1, but in different embodiments the ratio of larger cells to smaller cells could be larger or smaller. It is also contemplated that the cells 1020 could be formed from two smaller bifacial photovoltaic cells electrically connected in parallel, which are in turn connected in their corresponding string. In such an arrangement, the cells would produce a current corresponding to one cell having a surface area equivalent to the two cells which are connected in parallel.

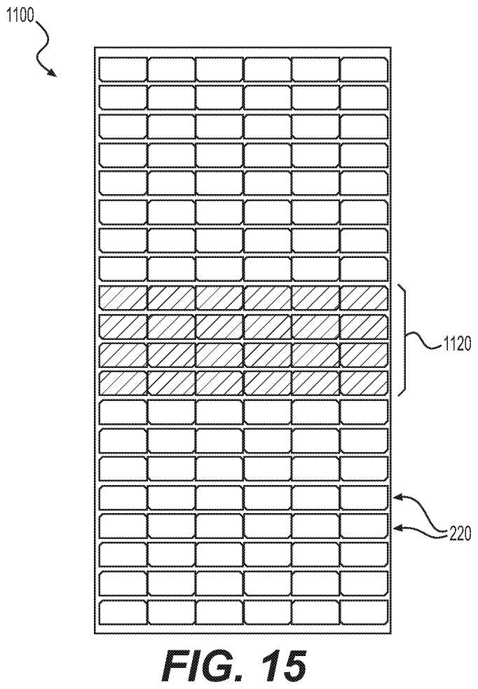

With reference to FIG. 15, another non-limiting embodiment of a bifacial solar panel 1100 to be mounted in the single-axis tracker 120 will now be described. Elements of the solar panel 1100 that are similar to those of the solar panel 200 retain the same reference numeral and will generally not be described again.

The panel 110 includes two types of bifacial photovoltaic cells supported by the transparent layers 210, 212. The first group of cells 220 have a given efficiency and are generally disposed in an array as with panel 200, other than in a central portion of the panel 1100. Disposed in the central portion of the panel 1100, the second type of cell 1120 are similar in layout, size, and arrangement, but have an efficiency which is greater than the efficiency of the cells 220. The cells 220 are electrically connected in series to the cells 1120, but it is contemplated that only some of the cells 220, 1120 could be connected together in series.

As described before, when a portion of the mounting assembly 120 obscures a portion of the bottom side of the panel 1100, one or more of the cells 1120 receives less irradiance than the cells 220 via the bottom side of the panel 1100 due to obscuration by the mounting assembly 120. In the present embodiment, however, a subset of cells in the potentially shaded region have been replaced with the higher efficiency bifacial photovoltaic cells 1120 (identified by cross-hatching in the Figure). As such, at least a portion of the irradiance obscured by the mounting assembly 120 is at least partially compensated by the greater efficiency to collect irradiance of the cells 1120 compared to the cells 220. For the same top side irradiance, the cells 1120 create a greater current than the cells 220. As such, when the cells 220 are generating current from both top and bottom side irradiance, the cells 1120 create a similar current due to their top side irradiance even when the bottom side of some or all of the cells 1120 are shaded.

The mixed arrangement of two different efficiency cells 220, 1120 aids in balancing current flow, while also being slightly more cost effective. The more efficient cells 1120 are generally more expensive but are only used in a small area of the panel 1100. While the panel 1100 includes higher efficiency cells 1120 in the center four rows, it is contemplated that the panel 1100 could include more or fewer higher efficiency cells 1120.

The various different embodiments described above provide different single structures which are different ways of forming bifacial solar panels and solar panel assemblies which address the issue of bottom- or rear-side shadowing. The technology, however, is not so restricted. Other embodiments of the technology will employ two or more of those structures together to achieve the desired result. For example, an embodiment according to the present technology could include both cells with different sizes and/or different efficiencies, and which could be combined in some cases with the light redirecting structures.

In any of the described and illustrated embodiments, it is contemplated that the number and arrangement of photovoltaic cells could be different. Each and any of the above described panels could include more or fewer total photovoltaic cells. The particular distribution of the photovoltaic cells could also vary, depending on any particular embodiment.

Modifications and improvements to the above-described embodiments of the present technology may become apparent to those skilled in the art. The foregoing description is intended to be exemplary rather than limiting.

1. A bifacial photovoltaic solar panel having a first side and a second side opposite the first side, the panel comprising:
at least one transparent layer;
a plurality of bifacial photovoltaic cells supported by the at least one transparent layer, the plurality of cells being distributed across the at least one transparent layer,
a first side of each of the photovoltaic cells being positioned and arranged to absorb irradiance incident on the first side of the panel and a second side of each of the photovoltaic cells being positioned and arranged to absorb irradiance incident on the second side of the panel; and
at least one optical element supported by the at least one transparent layer and disposed between some of the plurality of cells,
when in use,
the panel being connected to a mounting assembly, and
at least a portion of the mounting assembly obscuring at least a portion of the second side of the panel, the second sides of a subset of cells of the plurality of cells receiving less irradiance via the second side of the panel than the second sides of other cells of the plurality of cells due to obscuration by the mounting assembly,
the at least one optical element being structured, positioned, oriented and arranged within the panel to direct at least some irradiance incident thereon via the first side of the panel onto the first sides of the subset of cells whereby at least a portion of irradiance having been prevented from reaching the second sides of the cells of the subset of cells by the mounting assembly is compensated for by irradiance reflected by the at least one optical element onto the first sides of the cells of the subset of cells.

2. The panel of claim 1, wherein the at least one optical element is at least one reflective optical element.

3. The panel of claim 1, wherein:
the at least one optical element is three optical elements;
each optical element extends across the panel;
one of the optical elements extending through a center of the panel; and
remaining elements of the two optical elements are parallel to and disposed on opposite sides of the optical element extending through the center of the panel.

4. The panel of claim 1, wherein:
the at least one optical element is two reflective optical elements;
each reflective optical element extends across the panel; and
the reflective optical elements are disposed on opposite sides of a center of the panel.

5. The panel of claim 1, wherein the at least one optical element is disposed adjacent an exterior edge of the panel.

6. The panel of claim 1, wherein:
the mounting assembly includes a frame that supports exterior edges of the panel;
the at least one optical element is four reflective optical elements;
each reflective optical element is disposed adjacent to one of the exterior edges of the panel; and
at least some of the subset of cells are disposed adjacent the reflective optical elements.

7. The panel of claim 1, wherein:
the at least one transparent layer is a first transparent layer;
the panel further comprises a second transparent layer; and
the plurality of photovoltaic cells are disposed between the first transparent layer and the second transparent layer.

8. The panel of claim 1, wherein the plurality of bifacial photovoltaic cells are electrically connected in series.

9. The panel of claim 1, wherein at least one of the subset of cells and at least one of the other cells are electrically connected in series.

10. The panel of claim 2, wherein the at least one reflective optical element comprises a series of reflective facets extending across a width of the panel generally parallel to the subset of cells.

11. The panel of claim 1, wherein a spacing between rows of the subset of cells and rows of the other cells of the plurality of cells is greater than a spacing between rows of the other cells of the plurality of cells.

12. A solar panel assembly comprising:
at least one bifacial solar panel of claim 1; and
the mounting assembly connected to the at least one panel.

13. The solar panel assembly of claim 12, wherein:
the mounting assembly includes at least one torsion tube;
the at least one panel is connected to the at least one torsion tube; and
the at least one optical element extends across the at least one panel parallel to the at least one torsion tube.

14. The solar panel assembly of claim 12, wherein:
the mounting assembly includes a torsion tube;
the at least one panel is a first panel and a second panel;
the at least one optical element of the first panel is disposed adjacent a first exterior edge of the first panel;
the at least one optical element of the second panel is disposed adjacent a first exterior edge of the second panel;
the first panel is connected to the torsion tube proximate the corresponding first exterior edge;
the second panel is connected to the torsion tube proximate the corresponding first exterior edge; and
the at least one optical element of the first panel, the at least one optical element of the second panel, and the torsion tube are arranged parallel to one another.

15. The solar panel assembly of claim 12, wherein:
the mounting assembly includes two support trusses;
the at least one panel is connected to the support trusses; and
the at least one optical element extends across the at least one panel parallel to the support trusses.

16. The solar panel assembly of claim 12, wherein:
the mounting assembly includes a rectangular frame;
the at least one panel is supported by the rectangular frame via exterior edges of the at least one panel;
the at least one optical element is four reflective optical elements; and
each reflective optical element is disposed adjacent one of the exterior edges of the panel; and
at least some of the subset of cells are disposed adjacent the reflective optical elements.

17.-19. (canceled)

20. A bifacial photovoltaic solar panel having a first side and a second side opposite the first side, the panel comprising:
at least one transparent layer;
a plurality of bifacial photovoltaic cells supported by the at least one transparent layer, the plurality of cells being distributed across the at least one transparent layer,
a first side of each of the photovoltaic cells being positioned and arranged to absorb irradiance incident on the first side of the panel and a second side of each of the photovoltaic cells being positioned and arranged to absorb irradiance incident on the second side of the panel; and
at least one optical element supported by the at least one transparent layer and disposed between some of the plurality of cells,
the at least one optical element being structured, positioned, oriented and arranged within the panel to direct at least some irradiance incident thereon via the first side of the panel onto the first sides of a subset of cells disposed around the at least one optical element,
a spacing between rows of the subset of cells and rows of other cells of the plurality of cells being greater than a spacing between rows of the other cells of the plurality of cells.

21.-23. (canceled)

24. A bifacial photovoltaic solar panel comprising:
at least one transparent layer;
a first plurality of bifacial photovoltaic cells supported by the at least one transparent layer, each photovoltaic cell of the first plurality of cells having a first efficiency;
a second plurality of bifacial photovoltaic cells supported by the at least one transparent layer, each photovoltaic cell of the second plurality of cells having a second efficiency,
each bifacial photovoltaic cell of the first plurality and of the second plurality having a first side and a second side,
the second efficiency being greater than the first efficiency; and
when in use,
the panel being connected to a mounting assembly,
the first side of each cell being arranged and oriented to receive direct solar irradiance via a first side of the panel,
at least a portion of the mounting assembly obscuring at least a portion of a second side of the panel, the second side of the panel being opposite the first side of the panel,
at least a subset of the second plurality of cells receiving less irradiance than other cells via the second side of the panel due to obscuration by the mounting assembly, and
at least a portion of irradiance obscured by the mounting assembly on the second side of the subset of the second plurality of cells being compensated by greater efficiency to collect irradiance of the subset of the second plurality of cells compared to the first plurality of cells.

25. The panel of claim 24, wherein at least some of the first plurality of cells are electrically connected in series to at least some of the second plurality of cells.
